(19) United States
(12) Patent Application Publication
(10) Pub. No.: US 2010/0316791 A1
(43) Pub. Date: Dec. 16, 2010

(54) SUPERCRITICAL VAPOR DEPOSITION METHOD AND SYSTEM

(75) Inventor: Tsao-Jen Lin, Minhsiung Township (TW)

Correspondence Address: KIRTON AND MCCONKIE, 60 EAST SOUTH TEMPLE,, SUITE 1800, SALT LAKE CITY, UT, 84111, US

(73) Assignee: NATIONAL CHUNG CHENG UNIVERSITY, Minhsiung Township (TW)

(21) Appl. No.: 12/510,642

(22) Filed: Jul. 28, 2009

(30) Foreign Application Priority Data
Jun. 15, 2009 (TW) 098119956

(51) Int. Cl. C23C 16/44; C23C 16/46

(52) U.S. Cl. 427/69; 427/248.1; 427/255.6; 118/725

(57) ABSTRACT

A supercritical vapor deposition method includes the following steps. Firstly, a fluid is provided. Then, the pressure of the fluid is increased to a supercritical phase such that the fluid becomes a supercritical solvent. Then, a coating substance is dissolved in the supercritical solvent, thereby preparing a solubility equilibrium supercritical solution. Then, a substrate is provided on a heating base, which is immersed in the solubility equilibrium supercritical solution. Afterwards, the heating base is heated to have the solubility equilibrium supercritical solution generate a precipitation driving force, so that the coating substance is precipitated out and deposited on the substrate as a film.

### FIELD OF THE INVENTION

The present invention relates to a vapor deposition method and a vapor deposition system, and more particularly to a supercritical vapor deposition method and a supercritical vapor deposition system.

### BACKGROUND OF THE INVENTION

Recently, an organic light-emitting diode (OLED) display has been developed due to their self-emissive property (without using a backlight). In addition, the OLED display has many advantages such as a wide viewing angle, a higher contrast, low energy consumption, a rapid response and a simplified fabricating process. The significant benefits of the OLED display over the traditional thin film transistor liquid crystal display (TFT-LCD) are that the OLED display has a wider viewing angle, better color performance and higher illuminating efficiency. Although the OLED display is very perfect in its performance, the OLED display is not cost-effective. For enhancing the competitiveness of the OLED display, the fabricating process of the OLED display should be further improved. Conventionally, there are three processes for fabricating OLED films.

A first fabricating process is vacuum evaporation. Such a technique consists of pumping a vacuum chamber to pressures of less than 10⁻⁶ torr and heating a material to produce a flux of vapor in order to deposit the material onto a surface. Since the raw-material utilization is very low (usually less than 5%) and the vacuum chamber is operated at a very low pressure, such a technique is insufficient and expensive. On the other hand, if the boiling point of the coating material is too high, a high heating temperature and a high vacuum degree are necessary for performing the vacuum thermal evaporation. Due to the restriction of the glass temperature of the coating material, the application range of the vacuum evaporation is limited.

A second fabricating process is an organic vapor deposition process. This technique uses an organic solvent to provide sufficient vapor pressure of the OLED material, so that the demand on the vacuum degree of the vacuum chamber is less stringent (e.g. about 10⁻⁴ torr). The organic vapor deposition process results in uniform coating thickness and reduced materials waste (for example the raw-material utilization is increased to about 50%). Although the demand on the vacuum degree of the vacuum chamber is less stringent, a great deal of heat is necessary for vaporizing the organic material. In other words, the organic vapor deposition process is not cost-effective.

A third fabricating process is an inkjet process. Such a technique has better raw-material utilization. However, the film forming quality is unsatisfied and difficult to be controlled. In addition, the inkjet process is operated in a vacuum condition. That is, the applications thereof are limited.

In the above OLED film fabricating processes, vacuum evaporation and organic vapor deposition are widely used. Since the organic material for forming the OLED film is reactive to water and oxygen, the OLED device fabricated by vacuum evaporation or organic vapor deposition has reduced brightness value or increased driving voltage, and possibly results in dark spots or a short-circuited problem. For avoiding these drawbacks, vacuum evaporation and organic vapor deposition should be performed in the vacuum condition. In addition, since it is difficult to control the process of packaging the OLED device, the use life is shortened and the application thereof is limited.

Therefore, there is a need of providing improved system and method for producing OLED films so as to obviate the drawbacks encountered from the prior art.

### SUMMARY OF THE INVENTION

It is an object of the present invention to provide a supercritical vapor deposition system and a supercritical vapor deposition method for fabricating opto-electronic devices such as small molecule OLED devices or organic solar cells. By using the system and method of the present invention, the film-forming speed and the raw-material utilization are both enhanced in order to replace the current vacuum evaporation process. In addition, the system and method of the present invention can be used in the deposition process of forming organic conductor layers and water-oxygen barrier layers of flexible light-emitting elements. As such, the fabricating processes are more consistent and the possibility of causing damage by water and oxygen will be minimized.

An object of the present invention provides a supercritical vapor deposition system and a supercritical vapor deposition method by using a supercritical carbon dioxide solvent to dissolve the solute (e.g. an organic polymeric substance). After the solute is dissolved in the supercritical carbon dioxide solvent to prepare a solubility equilibrium supercritical solution, the substrate is heated in order to reduce the solubility of the solute. As a consequence, the solute is precipitated out of the solubility equilibrium supercritical solution and deposited on the substrate as a film. Since the supercritical carbon dioxide solvent is a green solvent and has low critical temperature and pressure, the system and method of the present invention are environmentally friendly and cost-effective. In addition, after the pressure of the solubility equilibrium supercritical solution is relieved, the carbon dioxide gas is separated from the OLED film and thus no residual solvent is remained on the film.

A further object of the present invention provides a supercritical vapor deposition system and a supercritical vapor deposition method by using the high pressure of the water-free and oxygen-free supercritical phase to replace the vacuum condition. As such, the problems caused by vacuum evaporation or organic vapor deposition (e.g. reduced brightness value, increased driving voltage, dark spots or a short-circuited problem) will be overcome. Moreover, in comparison with the OLED film fabricated by the inkjet process or the spin coating process, the film forming quality fabricated by the system and method of the present invention is enhanced.

A still object of the present invention provides a supercritical vapor deposition system and a supercritical vapor deposition method for controlling the film thickness of less than 100 nm and the root mean square (RSM) of the film roughness less than 0.5 nm. The films fabricated by the system and method of the present invention comply with the requirement of OLED devices. Since carbon dioxide is water-free and oxygen-free, the OLED film could be protected from being invaded. In addition, since the supercritical carbon dioxide solvent is non-toxic and reusable, the system and method of the present invention are very environmentally friendly.

In accordance with an aspect of the present invention, there is provided a supercritical vapor deposition method. The supercritical vapor deposition method includes the following steps. Firstly, a fluid is provided. Then, the pressure of the fluid is increased to a supercritical phase such that the fluid becomes a supercritical solvent. Then, a coating substance is dissolved in the supercritical solvent, thereby preparing a solubility equilibrium supercritical solution. Then, a substrate is provided on a heating base, which is immersed in the solubility equilibrium supercritical solution. Afterwards, the heating base is heated to have the solubility equilibrium supercritical solution generate a precipitation driving force, so that the coating substance is precipitated out and deposited on the substrate as a film.

In accordance with another aspect of the present invention, there is provided a supercritical vapor deposition system. The supercritical vapor deposition system includes a pressure-enhancing unit, a dissolving unit and a film-forming unit. The pressure-enhancing unit includes a high pressure pump for increasing the pressure of a fluid to a supercritical phase such that the fluid becomes a supercritical solvent. The dissolving unit includes a dissolving tank in communication with the pressure-enhancing unit for receiving the supercritical solvent from the pressure-enhancing unit. A coating substance is dissolved in the supercritical solvent, thereby preparing a solubility equilibrium supercritical solution. The film-forming unit includes a film-forming tank in communication with the dissolving unit for receiving the solubility equilibrium supercritical solution. A heating base is mounted within the film-forming tank. A substrate is provided on the heating base. The heating base is heated to have the solubility equilibrium supercritical solution generate a precipitation driving force, so that the coating substance is precipitated out and deposited on the substrate as a film.

In accordance with a further aspect of the present invention, there is provided a supercritical vapor deposition system. The supercritical vapor deposition system includes a pressure-enhancing unit and a film-forming unit. The pressure-enhancing unit includes a high pressure pump for increasing the pressure of a fluid to a supercritical phase such that the fluid becomes a supercritical solvent. The film-forming unit includes a film-forming tank in communication with the pressure-enhancing unit for receiving the supercritical solvent from the pressure-enhancing unit. A heating base is mounted within the film-forming tank. A substrate is provided on the heating base, wherein a coating substance is dissolved in the supercritical solvent so as to prepare a solubility equilibrium supercritical solution. The heating base is heated to have the solubility equilibrium supercritical solution generate a precipitation driving force, so that the coating substance is precipitated out and deposited on the substrate as a film.

The above contents of the present invention will become more readily apparent to those ordinarily skilled in the art after reviewing the following detailed description and accompanying drawings, in which:

### BRIEF DESCRIPTION OF THE DRAWINGS

FIG. 1 is a schematic diagram illustrating the architecture of a supercritical vapor deposition system according to an embodiment of the present invention;

FIG. 2 is a plot illustrating the relationship between the nucleus radius of the precipitated solid solute and the free energy change;

FIG. 3 is a plot illustrating the relationship between the Miers Theory concentration and the driving force;

FIG. 4 schematically illustrates the comparison of a homogeneous nucleation mechanism with a heterogeneous nucleation mechanism;

FIGS. 5A, 5B and 5C schematically illustrate three film growth modes;

FIG. 6 is a flowchart illustrating the supercritical vapor deposition method of the present invention; and

FIG. 7 is a schematic diagram illustrating the architecture of a supercritical vapor deposition system according to another embodiment of the present invention.

### DETAILED DESCRIPTION OF THE PREFERRED EMBODIMENT

The present invention will now be described more specifically with reference to the following embodiments. It is to be noted that the following descriptions of preferred embodiments of this invention are presented herein for purpose of illustration and description only. It is not intended to be exhaustive or to be limited to the precise form disclosed.

The present invention relates a supercritical vapor deposition system and a supercritical vapor deposition method. Hereinafter, the present invention will be illustrated by referring the system and method for depositing an OLED film. Nevertheless, the system and method of the present invention could be applied to fabricate films of small molecule OLED devices, organic solar cells, or the like.

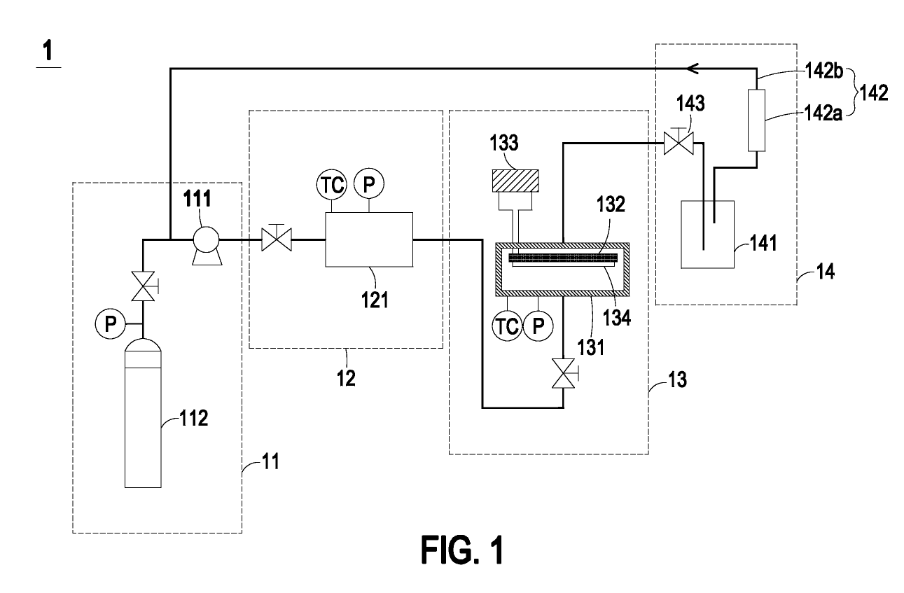

FIG. 1 is a schematic diagram illustrating the architecture of a supercritical vapor deposition system according to an embodiment of the present invention. As shown in FIG. 1, the supercritical vapor deposition system 1 comprises a pressure-enhancing unit 11, a dissolving unit 12, a film-forming unit 13 and a pressure-relieving unit 14. In this embodiment, the supercritical vapor deposition system is used for producing an OLED film.

The pressure-enhancing unit 11 includes a high pressure pump 111 for increasing the pressure of a fluid to a supercritical phase or a supercritical solvent. In this embodiment, the fluid is gaseous or liquid carbon dioxide provided by a carbon dioxide cylinder 112. The carbon dioxide in the supercritical phase is referred herein as a supercritical carbon dioxide (SCCO2) solvent.

The supercritical carbon dioxide solvent is then transmitted to the dissolving unit 12. The dissolving unit 12 has a dissolving tank 121, which is in communication with the pressure-enhancing unit 11. Next, a coating substance (e.g. tris-(8-hydroxyquinoline) aluminum (AlQ3)) is dissolved in the supercritical carbon dioxide solvent by properly controlling the pressure and temperature of the dissolving tank 121, thereby preparing a solubility equilibrium supercritical solution of the supercritical carbon dioxide solvent and the coating material AlQ3.

The solubility equilibrium supercritical solution is then introduced into the film-forming unit 13. The film-forming unit 13 includes a film-forming tank 131 and a heating base 132. The heating base 132 is mounted within the film-forming tank 131. A substrate 134 is fixed on the heating base 132. An example of the substrate 134 is an indium tin oxide (ITO) glass. Since the film-forming unit 13 is in communication with the dissolving unit 12, the solubility equilibrium supercritical solution in the dissolving tank 121 could be transmitted to the film-forming tank 131. The pressure and temperature of the film-forming tank 131 are adjustable in order to perform a film-forming operation. The heating base 132 is heated by an external heater 133. As the temperature of the heating base 132 is increased, the precipitation driving force of the solubility equilibrium supercritical solution is generated because of the temperature difference. Consequently, the coating substance (e.g. AlQ3) is precipitated out of the solubility equilibrium supercritical solution and deposited on the substrate 134 as a film.

After the film-forming procedure is done, the pressure of the solubility equilibrium supercritical solution is relieved, and thus the solubility equilibrium supercritical solution is split into a gas-liquid mixture. The pressure-relieving unit 14 is in communication with the film-forming unit 13. The pressure-relieving unit 14 includes an on-off valve 143. By the pressure-relieving unit 14, the solubility equilibrium supercritical solution is split into a gas-liquid mixture. The pressure-relieving unit 14 further includes a pressure-relieving separation tank 141 and a recovery device 142. When the gas-liquid mixture is transmitted to the pressure-relieving separation tank 141, the carbon dioxide is returned to a gaseous state. The recovery device 142 is in communication the pressure-relieving separation tank 141 and the pressure-enhancing unit 11. By the recovery device 142, the gas separated from the pressure-relieving separation tank 141 is recycled to the pressure-enhancing unit 11. The recovery device 142 includes a filter 142a and a recovery pipe 142b. The recovery device 142 is used for filtering off the contaminant contained in the gas (i.e. carbon dioxide). The filtered gas is transmitted to the pressure-enhancing unit 11 to be re-used. As a consequence, the fabricating cost associated with the supply of the carbon dioxide from the carbon dioxide cylinder 112 is reduced.

The supercritical vapor deposition system of the present invention can be used for fabricating OLED films and replace the conventional systems of fabricating OLED films. In comparison with the conventional systems, the supercritical vapor deposition system of the present invention is easily operated, power-saving and environmentally-friendly. Since no water or oxygen is included in the supercritical solvent and the supercritical solution, the supercritical vapor deposition system of the present invention uses a high-pressure condition to deposit a film in replace of the vacuum condition. By heating up the substrate, the solute contained in the solubility equilibrium supercritical solution is precipitated out and deposited on the substrate. The principle of forming the film on the substrate according to the present invention will be illustrated in more details as follows.

Generally, the tendency of precipitating out a solute from a solution is dependent on the precipitation driving force of the solution. The term precipitation driving force indicates a super-saturation ratio (RS) of solute concentration to solute solubility at the given temperature. If RS>1, it is meant that the solute solubility is lower than the solute concentration. Under this circumstance, nucleation and crystal growth occur. In other words, the rate of film growth and the critical nucleus size are changeable by controlling the magnitude of the super-saturation ratio. According to the fact that the solubility of the supercritical solution is varied by changing the temperature and pressure, nano-scale particles or micro-scale particles could be prepared in order to further produce the film. In accordance with the present invention, the supercritical solution is used for producing a nano-scale film according to the solubility difference resulting from a temperature change.

From a thermodynamic viewpoint, the critical nucleus size is adjusted by controlling the magnitude of the super-saturation ratio (RS) according to the following equations:

$$\begin{matrix}Δ G ( r ) = 4 π {r}^{2} σ + \frac{4}{3} π {r}^{3} Δ {G}_{V} & ( 1 ) \\ Δ {G}_{V} = - \frac{kT}{v} ln ( RS ) & ( 2 )\end{matrix}$$

where:
ΔG is total free energy,
σ is the surface tension required for balancing molecular accumulation, and
ΔGᵥ is the free energy change during precipitation

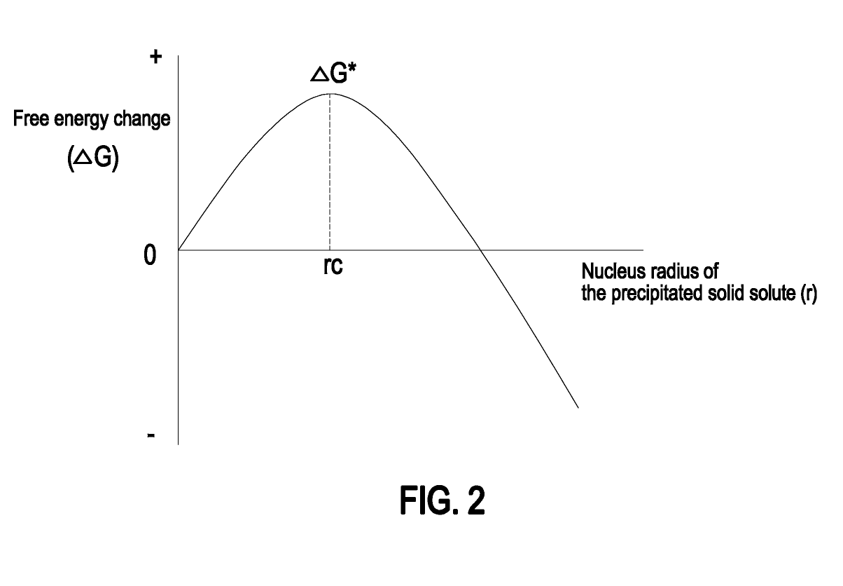

From the relationship between the nucleus radius and the free energy change as depicted in the equation (1), when the energy offered by the driving force is greater than the surface free energy, a stabilized solid begins to appear. FIG. 2 is a plot illustrating the relationship between the nucleus radius of the precipitated solid solute and the free energy change. As shown in FIG. 2, the free energy change is ΔG* at the minimum critical nucleus radius r_{c}. The equation (1) is subject to a differentiation, thereby obtaining the equations (3) and (4).

$$\begin{matrix}{r}_{c} = - \frac{2 σ}{Δ {G}_{V}} & ( 3 ) \\ Δ {G}^{*} = \frac{16 π {σ}^{2}}{3 Δ {G}_{V}^{2}} & ( 4 )\end{matrix}$$

As the ratio RS is increased and the free energy change ΔGᵥ is decreased, a smaller critical nucleus radius r_{c} is obtained.

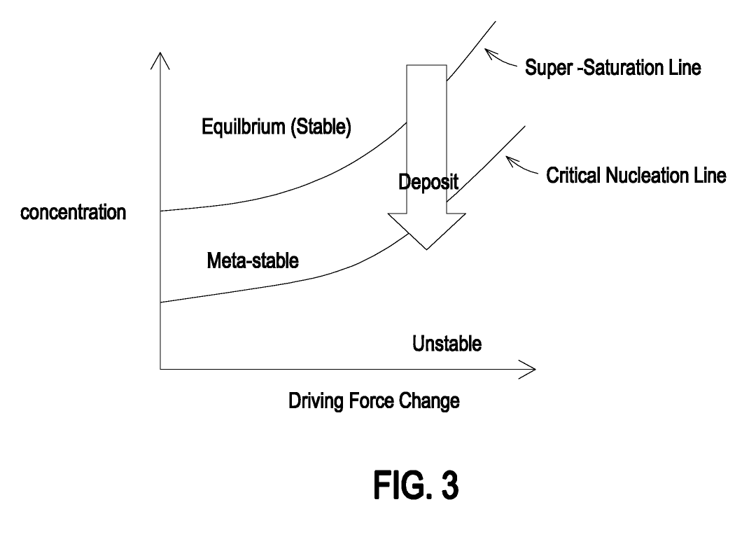

The factors influencing the tendency of precipitating out a solute from a solution include the precipitation driving force of the solution at a specified concentration and the super-saturation state of the solution. In some situations (e.g. a meta-stable state), no solute is precipitated out even if the above conditions are satisfied. FIG. 3 is a plot illustrating the relationship between the Miers Theory concentration and the driving force. As the super-saturation ratio is gradually increased, the tendency of precipitating out the solute is changed from the equilibrium (stable) state to an unstable state through a meta-stable state. Under this circumstance, nucleation and crystal growth occur.

As known, the super-saturation ratio is increased by increasing the solute concentration or decreasing the solute solubility. Since the solute concentration is easily controlled, the super-saturation ratio is usually adjusted by changing the solute concentration. From a thermodynamic viewpoint, the solute concentration is related to a solubility parameter (δ). The solubility parameter δ could be depicted by the equation (5). That is, the solubility parameter δ is equal to a square root of a molar binding energy divided by a unit volume. Moreover, the relationship between a solute B and a solvent A could be depicted by the equation (6). From the equation (6), if the difference between the solubility parameters δ of the solute B and a solvent A is smaller, the solubility is increased.

$$\begin{matrix}δ = {[ \frac{Δ {H}_{v} - RT}{v} ]}^{\frac{1}{2}} & ( 5 ) \\ ln {x}_{B} = - {{v}_{A} ( RT )}^{- 1} {( {δ}_{B} - {δ}_{A} )}^{2} & ( 6 )\end{matrix}$$

where,
ΔHᵥ is the enthaply for vaporizing a substance at the given temperature T, and v is a unit volume of the solution.

According to the van der Waals equation, a solubility empirical formula at the supercritical condition is depicted by the equation (7). That is, if the solubility parameter δ is in the range of ±1(cal/ml)^{1/2}, the substance has miscibility. The equation (8) is an empirical formula for illustrating the compressed gas.

$$\begin{matrix}δ = 1.25 {P}_{C}^{1 / 2} & ( 7 ) \\ δ = 1.25 {P}_{C}^{1 / 2} ( \frac{{ρ}_{rSCF}}{{ρ}_{rLiquid}} ) & ( 8 )\end{matrix}$$

where,
P_{c} is the critical pressure of a fluid (atm),
ρ_{rSEF} is a reduced density of the fluid in the supercritical phase,
ρ_{rLiquid} is a reduced density of the fluid in the liquid phase,
ρᵣ is a reduced density equal to a density ratio of ρ/ρ_{C} at the critical point.

According to the equation (8), the solubility parameter of the supercritical fluid is calculated and the solute concentration is estimated. Since the solubility is influenced by the density change of the supercritical fluid and the density is a function of temperature and pressure, the variations of the temperature and pressure in the supercritical condition could be deemed as precipitation driving forces.

From a dynamic viewpoint, the profile and densification of the film are also influenced by the intermolecular force. The motion of the surface molecules could be expressed as a diffusion coefficient (D) depicted by the equation (9):

D=D₀exp(−E_{B}/kT) (9)

where,
D₀ is a test frequency,
E_{b} is the molecular energy barrier,
k is Boltzmann constant, and
T is absolute temperature.

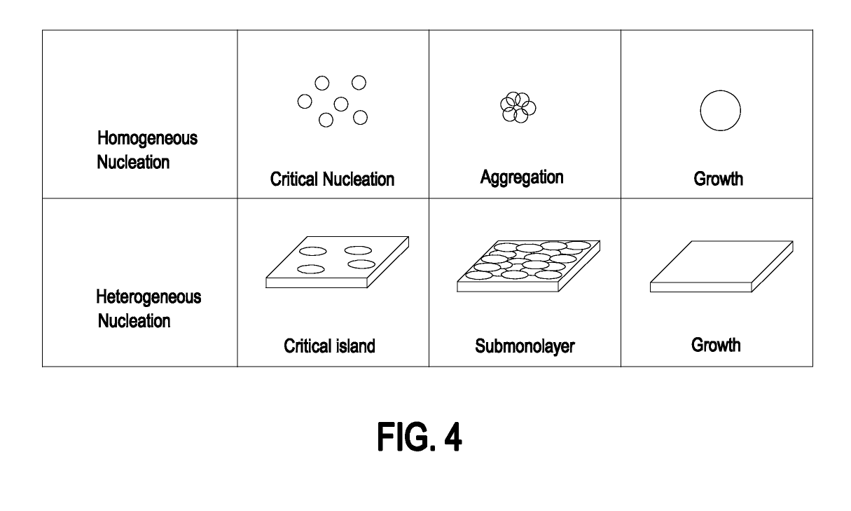

Generally, the nucleation mechanism is dependent on the precipitation driving force and the degree of directional uniformity. As shown in FIG. 4, the nucleation mechanisms are usually classified into the types, i.e. a homogeneous nucleation mechanism and a heterogeneous nucleation mechanism. The homogeneous nucleation mechanism occurs when the three-dimensional environment is homogeneous. The homogeneous nucleation mechanism includes steps of an initial critical nucleation, an aggregation and a final spherical feature (growth). The heterogeneous nucleation mechanism happens in the grain boundary and the dislocation interface. The heterogeneous nucleation mechanism includes the formation of critical islands, an aggregation between islands, and the film growth. The system and method of the present invention utilize the heterogeneous nucleation mechanism to form films. In the supercritical system, the nucleation resulting from precipitation should be carried out at high temperature. As the temperature is increased, the precipitation region resulting from super-saturation becomes narrower. In addition, during nucleation, the nucleation region is switched from the homogeneous nucleation region to the heterogeneous nucleation region. As the solubility or driving force is reduced, the nucleation region will only be in the homogeneous nucleation region. Under this circumstance, the film forming quality is deteriorated.

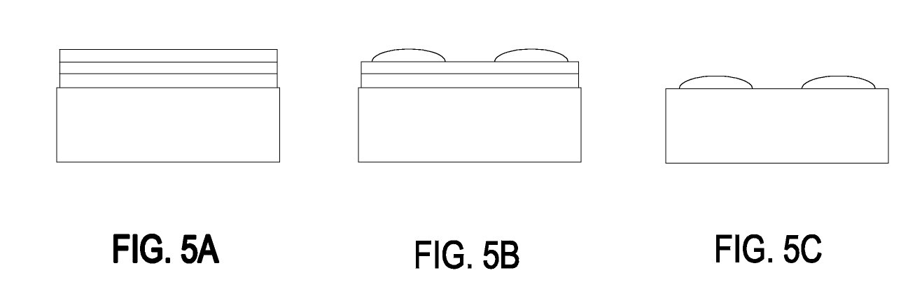

Moreover, there are three film growth modes, i.e. a layer-by-layer growth mode, an island growth mode and a layer-plus-island growth mode. These three modes are distinguished according to the affinity of the precipitated crystal nucleus to the substrate. FIGS. 5A, 5B and 5C schematically illustrate three film growth modes. In the layer-by-layer growth mode, the affinity of the precipitated crystal nucleus to the substrate is much larger than the intermolecular force. The affinity of the precipitated crystal nucleus to the substrate is usually resulted from chemical bonds or other special bonds. The layer-by-layer growth mode is also referred as a Frank-Van der Merwe mode (see FIG. 5A). Generally, most films grow in the island growth mode and the layer-plus-island growth mode. Since the stress of the precipitated crystal on the substrate is very large, a thin wetting layer is usually deposited on the substrate in order to overcome the physical stress. Next, a film in an island form is deposited on the wetting layer. As shown in FIG. 5B, such film growth mode is also referred as a Stranski-Krastanov mode. FIG. 5C is Volmer-Weber mode. After critical islands are generated, the critical islands are aggregated, moved and jointed. Next, an island-like growth structure is formed, the voids are filled and a continuous film formation is done.

From the above discussions, the operating pressure and temperature, the substrate temperature, the pressure relief speed, the deposition duration, the heat-treating duration and temperature are important operating parameters that have influence on the film thickness and the film roughness. As the deposition duration is extended, the film thickness is increased but the film roughness is also increased. Moreover, an additional heat-treating step is helpful for largely reducing the film roughness.

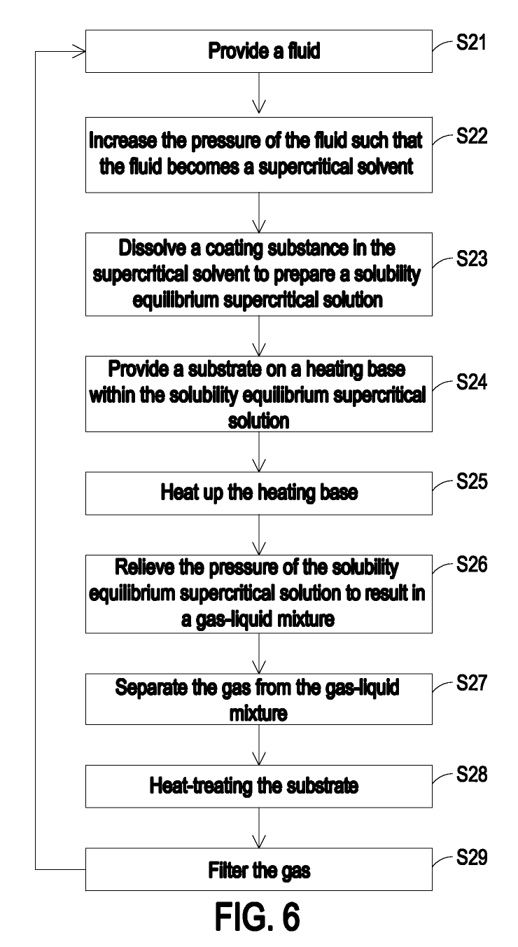

The present invention also relates to a supercritical vapor deposition method. FIG. 6 is a flowchart illustrating the supercritical vapor deposition method of the present invention. Hereinafter, the supercritical vapor deposition method will be illustrated with reference to FIG. 1 and FIG. 6.

First of all, a fluid is provided (Step S21). An example of the fluid includes but is not limited to carbon dioxide, which is provided by a carbon dioxide cylinder 112. In addition, the fluid could be recycled from the supercritical vapor deposition system.

Next, the pressure of the fluid is increased such that the fluid becomes a supercritical solvent (Step S22). In a case that the fluid is carbon dioxide, the supercritical solvent is a supercritical carbon dioxide (SCCO2) solvent. Since the critical temperature and pressure of carbon dioxide are very low, the pressure of carbon dioxide could be easily increased to the supercritical phase by the high pressure pump 111. The critical temperature for carbon dioxide is 31.1° C., and the critical pressure is 72.8 bar. In an embodiment, the pressure of the supercritical carbon dioxide (SCCO2) solvent is in a range between 10.2 MPa and 40.8 MPa. Preferably, the pressure of the supercritical carbon dioxide (SCCO2) solvent is 30.8 MPa.

Next, a coating substance is dissolved in the supercritical solvent to prepare a solubility equilibrium supercritical solution (Step S23). In this embodiment, the coating substance is AlQ3 in order to produce an OLED emissive layer. In some embodiments, the coating substance includes but is not limited to an inorganic compound, an organic polymeric compound or an organic metallic chelating compound. In this embodiment, the organic metallic chelating compound AlQ3 and the supercritical carbon dioxide (SCCO2) solvent are simultaneously introduced into the dissolving tank 121. By properly controlling the pressure and temperature of the dissolving tank 121, a solubility equilibrium supercritical solution is formed. An experiments shows that approximately 0.000048 g of AlQ3 could be dissolved into 100 ml of supercritical carbon dioxide (SCCO2) solvent at 30.6 MPa. The solubility equilibrium supercritical solution could be introduced into the film-forming tank 131.

Next, a substrate is provided and fixed on a heating base 132, which is immersed in the solubility equilibrium supercritical solution (Step S24). An example of the substrate is an indium tin oxide (ITO) glass. The pressure of the solubility equilibrium supercritical solution is adjusted to be in a range between 10.2 MPa and 40.8 MPa, preferably 30.8 MPa. In addition, the temperature of the solubility equilibrium supercritical solution is adjusted to be in a range between 32° C. and 38° C., preferably 35° C. In some embodiments, the substrate has been cleaned before mounted on the heating base 132.

Next, the heating base 132 is heated up to a temperature in a range between 35° C. and 80° C., preferably 60° C. (Step S25). For allowing the solubility equilibrium supercritical solution to generate the precipitation driving force, the temperature of the heating base 132 should be higher than the temperature of the solubility equilibrium supercritical solution. Consequently, the coating substance (e.g. AlQ3) is precipitated out of the solubility equilibrium supercritical solution and deposited on the substrate 134 as a film. The duration of forming the film is ranged from 5 to 30 minutes, for example 10 minutes. Depending on the duration, the film thickness is varied.

After the film-forming procedure is done, the pressure of the solubility equilibrium supercritical solution is relieved to result in a gas-liquid mixture (Step S26). The pressure is relieved at a rate of 5 ml/s to 30 ml/s at normal temperature and pressure. If the rate of relieving pressure is too fast, the integrity of the film is deteriorated. Whereas, if the rate of relieving pressure is too slow, the surface integrity is maintained but the film formation is very time consuming. It is preferred that the pressure is relieved at a rate of 15 ml/s.

Next, the gas-liquid mixture is introduced into the pressure-relieving separation tank 141 in order to separate the gas from the gas-liquid mixture (Step S27). By the recovery device 142, the gas separated from the pressure-relieving separation tank 141 is recycled to the pressure-enhancing unit 11 to be re-used. Optionally, the gas could be filtered by a filter 142a in order to remove the contaminant contained in the gas (Step S29). On the other hand, the supercritical vapor deposition method of the present invention further comprises a step of heat-treating the substrate (Step S29). As such, the film becomes smooth and flat. In a case that the pressure of the solubility equilibrium supercritical solution is 30.6 MPa, the temperature of the heating base is 60° C. and the film-forming duration is 10 minutes, the temperature of the substrate could be increased to 80° C. (heat treatment) before the pressure-relieving procedure is completed. As such, the molecules on the film surface will move and thus an excellent surface profile will be obtained. The influence of the heat treatment on the film thickness is very tiny. A short period of heat treatment will influence the roughness of the film. For achieving a smooth and flat film, the duration of the heat treatment is ranged from 5 minutes to 30 minutes, preferably 5 minutes.

In some embodiments, the supercritical vapor deposition method could be performed on a batch-wise basis or continuously performed in order to increase the film thickness. In some embodiments, a protective cover (not shown) is disposed on the heating base 132. The protective cover could be folded or unfolded. In a case that the film-forming procedure is not done, the substrate could be sheltered by the protective cover in order to protect the substrate from be contaminated by the environmental particles. As such, the roughness of the substrate will not be influenced by the particles while maintaining the adsorption capability of the film. For performing the film-forming procedure, the substrate will no longer be sheltered by the protective cover.

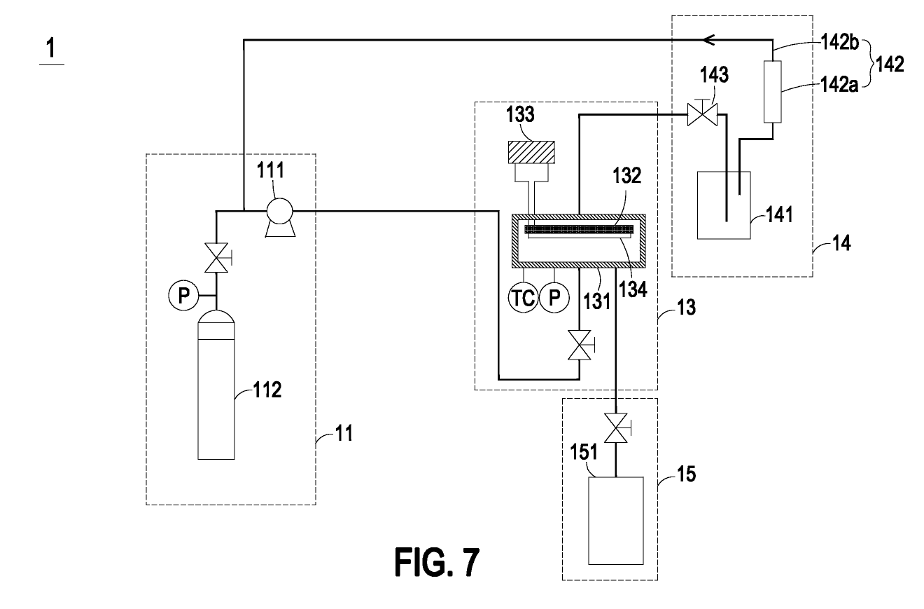

FIG. 7 is a schematic diagram illustrating the architecture of a supercritical vapor deposition system according to another embodiment of the present invention. As shown in FIG. 7, the supercritical vapor deposition system comprises a pressure-enhancing unit 11, a film-forming unit 13, a pressure-relieving unit 14 and a feeding unit 15. In this embodiment, the function of the dissolving unit 12 as shown in FIG. 1 is integrated into the film-forming unit 13. The feeding unit 15 is in communication with the film-forming tank 131 of the film-forming unit 13. The feeding unit 15 includes a feeding tank 151 for storing the coating substance (e.g. AlQ3). The coating substance is introduced into the film-forming tank 131, thereby preparing a solubility equilibrium supercritical solution of the supercritical carbon dioxide solvent and the coating material AlQ3. The operating principles of the supercritical vapor deposition system of FIG. 6 are substantially identical to those illustrated in FIG. 1, and are not redundantly described herein.

In the above embodiments, the organic metallic chelating compound AlQ3 is dissolved in the supercritical carbon dioxide (SCCO2) solvent, thereby preparing a solubility equilibrium supercritical solution. By heating up the heating base, the solubility of the organic metallic chelating compound AlQ3 in the supercritical carbon dioxide (SCCO2) solvent is reduced, and thus the organic metallic chelating compound AlQ3 is precipitated out and deposited on the substrate as a film. Experiments demonstrate that the film thickness is ranged from 10 nm to 100 nm and the root mean square (RSM) of the film roughness is less than 0.5 nm under the above operating conditions. In other words, the films fabricated by the system and method of the present invention comply with the requirement of OLED devices. Moreover, in comparison with the procedure of creating vacuum, the procedure of increasing the pressure is relatively quick. Since carbon dioxide is water-free and oxygen-free, the OLED film could be protected from being invaded. In addition, since the supercritical carbon dioxide solvent is non-toxic and reusable, the system and method of the present invention are very environmentally friendly. In comparison with the prior art, the system and method of the present invention have many benefits.

From the above description, the supercritical vapor deposition system and the supercritical vapor deposition method of the present invention are also applicable for fabricating films of opto-electronic devices such as small molecule OLED devices or organic solar cells. In comparison with the conventional fabricating method and system, the supercritical vapor deposition system and method of the present invention have higher raw-material utilization and can form film at a faster rate. The system and method of the present invention can replace the conventional vacuum evaporation process. In addition, the system and method of the present invention can be used in the deposition process of forming organic conductor layers and water-oxygen barrier layers of flexible light-emitting elements. As such, the fabricating processes are more consistent and the possibility of causing damage by water and oxygen will be minimized.

In a case that the conventional inkjet process or spin coating process is used to fabricate the OLED film, the film is readily damaged by the small molecule and thus multi-layered structure fails to be formed. Whereas, the OLED film fabricated by the system and method of the present invention has good film forming quality. The system and method of the present invention use a supercritical carbon dioxide solvent to dissolve the solute (e.g. an organic polymeric substance). After the solute is dissolved in the supercritical carbon dioxide solvent to prepare a solubility equilibrium supercritical solution, the substrate is heated in order to reduce the solubility of the solute. As a consequence, the solute is precipitated out of the solubility equilibrium supercritical solution and deposited on the substrate as a film. Since no residual solvent is remained on the film, the system and method of the present invention are very cost-effective. Since the supercritical carbon dioxide solvent is a green solvent and has low critical temperature and pressure, the system and method of the present invention are environmentally friendly and cost-effective. The system and method of the present invention could be applied to fabricate films of small molecule OLED devices or organic solar cells in order to improve the film forming quality. In addition, the system and method of the present invention could be used to fabricate other thin films or surface coating films. The present invention can also be applied to fabricate emissive layers, conductor layers or barrier layers. The coating substance includes an inorganic compound, an organic polymeric compound or an organic metallic chelating compound.

While the invention has been described in terms of what is presently considered to be the most practical and preferred embodiments, it is to be understood that the invention needs not be limited to the disclosed embodiment. On the contrary, it is intended to cover various modifications and similar arrangements included within the spirit and scope of the appended claims which are to be accorded with the broadest interpretation so as to encompass all such modifications and similar structures.

What is claimed is:

1. A supercritical vapor deposition method comprising:
(a) providing a fluid;
(b) increasing the pressure of said fluid to a supercritical phase such that said fluid becomes a supercritical solvent;
(c) dissolving a coating substance in said supercritical solvent, thereby preparing a solubility equilibrium supercritical solution;
(d) providing a substrate on a heating base, which is immersed in said solubility equilibrium supercritical solution; and
(e) heating up said heating base to have said solubility equilibrium supercritical solution generate a precipitation driving force, so that said coating substance is precipitated out and deposited on said substrate as a film.

2. The supercritical vapor deposition method according to claim 1 wherein said fluid is carbon dioxide, and said supercritical solvent is a supercritical carbon dioxide solvent.

3. The supercritical vapor deposition method according to claim 1 wherein said coating substance includes an inorganic compound, an organic polymeric compound or an organic metallic chelating compound.

4. The supercritical vapor deposition method according to claim 3 wherein said organic metallic chelating compound includes tris-(8-hydroxyquinoline) aluminum.

5. The supercritical vapor deposition method according to claim 1 wherein substrate is an indium tin oxide glass.

6. The supercritical vapor deposition method according to claim 1 wherein in said step (e), the pressure of said solubility equilibrium supercritical solution is adjusted to be in a range between 10.2 MPa and 40.8 MPa, and the temperature of said solubility equilibrium supercritical solution is adjusted to be in a range between 32° C. and 38° C.

7. The supercritical vapor deposition method according to claim 1 wherein in said step (e), said heating base is heated up to a temperature in a range between 35° C. and 80° C.

8. The supercritical vapor deposition method according to claim 1 wherein in said step (e), said coating substance is deposited on said substrate for 5 to 30 minutes.

9. The supercritical vapor deposition method according to claim 1 wherein said film has a thickness in a range from 10 nm to 100 nm, and said film has a roughness less than 0.5 nm.

10. The supercritical vapor deposition method according to claim 1 further comprising a step (f) of relieving the pressure of said solubility equilibrium supercritical solution, thereby generating a gas-liquid mixture.

11. The supercritical vapor deposition method according to claim 10 wherein in said step (f), the pressure of said solubility equilibrium supercritical solution is relieved at a rate of 5 ml/s to 30 ml/s at normal temperature and pressure.

12. The supercritical vapor deposition method according to claim 10 wherein said step (f) further includes a sub-step of heat-treating said substrate, so that said film on said substrate is smooth and flat.

13. The supercritical vapor deposition method according to claim 10 wherein said step (f) further includes sub-steps of separating said gas from said gas-liquid mixture and reusing said gas.

14. A supercritical vapor deposition system comprising:
a pressure-enhancing unit including a high pressure pump for increasing the pressure of a fluid to a supercritical phase such that said fluid becomes a supercritical solvent;
a dissolving unit including a dissolving tank in communication with said pressure-enhancing unit for receiving said supercritical solvent from said pressure-enhancing unit, wherein a coating substance is dissolved in said supercritical solvent, thereby preparing a solubility equilibrium supercritical solution; and
a film-forming unit including a film-forming tank in communication with said dissolving unit for receiving said solubility equilibrium supercritical solution, a heating base being mounted within said film-forming tank, a substrate being provided on said heating base, wherein said heating base is heated to have said solubility equilibrium supercritical solution generate a precipitation driving force, so that said coating substance is precipitated out and deposited on said substrate as a film.

15. The supercritical vapor deposition system according to claim 14 wherein said film-forming unit further includes an external heater, which is in communication with said heating base for heating said heating base.

16. The supercritical vapor deposition system according to claim 14 further comprising a pressure-relieving unit in communication with said film-forming unit, wherein said pressure-relieving unit includes an on-off valve for relieving the pressure of said solubility equilibrium supercritical solution and splitting said solubility equilibrium supercritical solution into a gas-liquid mixture.

17. The supercritical vapor deposition system according to claim 16 wherein said pressure-relieving unit further comprises:
a pressure-relieving separation tank in communication with said film-forming unit for receiving said gas-liquid mixture and separating said gas from said gas-liquid mixture; and
a recovery device in communication said pressure-relieving separation tank and said pressure-enhancing unit for recycling said gas that is separated from said gas-liquid mixture to said pressure-enhancing unit.

18. The supercritical vapor deposition system according to claim 17 wherein said recovery device comprises a filter and a recovery pipe.

19. A supercritical vapor deposition system comprising:
a pressure-enhancing unit including a high pressure pump for increasing the pressure of a fluid to a supercritical phase such that said fluid becomes a supercritical solvent; and
a film-forming unit including a film-forming tank in communication with said pressure-enhancing unit for receiving said supercritical solvent from said pressure-enhancing unit, a heating base being mounted within said film-forming tank, a substrate being provided on said heating base, wherein a coating substance is dissolved in said supercritical solvent so as to prepare a solubility equilibrium supercritical solution, and said heating base is heated to have said solubility equilibrium supercritical solution generate a precipitation driving force, so that said coating substance is precipitated out and deposited on said substrate as a film.

20. The supercritical vapor deposition system according to claim 19 further comprising a feeding unit in communication with said film-forming unit for storing said coating substance and feeding said coating substance to said film-forming unit.
